(19) United States
(12) Patent Application Publication
(10) Pub. No.: US 2023/0299252 A1
(43) Pub. Date: Sep. 21, 2023

(54) LIGHT-EMITTING DIODE PACKAGE

(71) Applicant: Quanzhou Sanan Semiconductor Technology Co., Ltd., Quanzhou (CN)

(72) Inventors: Tianyu YAN, Xiamen (CN); Senpeng HUANG, Xiamen (CN); Dacheng LI, Xiamen (CN); Shunyi CHEN, Xiamen (CN); Changchin YU, Xiamen (CN)

(21) Appl. No.: 18/151,762

(22) Filed: Jan. 9, 2023

(30) Foreign Application Priority Data
Mar. 18, 2022 (CN) 202210269183.1

(51) Int. Cl. H01L 33/62; H01L 33/58

(52) U.S. Cl. CPC H01L 33/62; H01L 33/58

(57) ABSTRACT

A light-emitting diode (LED) package includes a packaging substrate having a first surface, an LED chip disposed on the first surface, and a light-transmissible unit disposed on the first surface and formed with an indentation defined by an indentation-defining wall which cooperates with the first surface to form a cavity in which the LED chip is enclosed. The indentation-defining wall includes a base part, a peripheral part, and a first connecting part that interconnects the base part and the peripheral part and that includes one of a curved surface, an inclined surface, and a combination thereof. Other two LED packages are also disclosed.

### CROSS-REFERENCE TO RELATED APPLICATION

This application claims priority to Chinese Invention Patent Application No. 202210269183.1, filed on Mar. 18, 2022, which is incorporated herein by reference in its entirety.

### FIELD

The disclosure relates to a semiconductor device, and more particularly to a light-emitting diode (LED) package.

### BACKGROUND

Light-emitting diode (LED) packages, according to the types of packaging materials, may be grouped into a glass-lens-structure LED package and a resin-structure LED package. However, for a resin-structure deep ultraviolet (DUV) LED package, the transparency of a resin material thereof tends to decline following exposure to ultraviolet (UV) light, which may affect the light extraction efficiency of the DUV LED package. Therefore, DUV LED is usually packaged as a glass-lens-structure DUV LED package.

Referring to FIG. 1, in formation of a conventional LED package, an LED chip 2 is usually covered by a lens structure 3 under a vacuum environment at high temperature, which would cause the lens structure 3 to suffer from both internal thermal stress and external pressure, particularly from a large amount of stress at a right angular portion of the lens structure 3. A lens structure 3 that is made from quartz glass might be fragile, and might be broken along the right angular portion when such lens structure 3 is subjected to excessive stress, causing the conventional LED package to fail, which greatly increases the packaging costs.

### SUMMARY

Therefore, an object of the disclosure is to provide a light-emitting diode (LED) package that can alleviate or eliminate at least one of the drawbacks of the prior art.

According to one aspect of the disclosure, the LED package includes a packaging substrate, an LED chip, and a light-transmissible unit. The packaging substrate has a first surface. The LED chip is disposed on the first surface. The light-transmissible unit is disposed on the first surface, and is formed with an indentation defined by an indentation-defining wall which cooperates with the first surface to form a cavity in which the LED chip is enclosed. The indentation-defining wall includes a base part, a peripheral part, and a first connecting part that interconnects the base part and the peripheral part and that includes one of a curved surface, an inclined flat surface, and a combination thereof.

According to another aspect of the disclosure, the LED package includes a packaging substrate, an LED chip, and a light-transmissible unit. The packaging substrate has a first surface. The LED chip is disposed on the first surface. The light-transmissible unit is disposed on the first surface, has a lower surface that contacts with the first surface, and is formed with an indentation defined by an indentation-defining wall which cooperates with the first surface to form a cavity in which the LED chip is enclosed. The indentation-defining wall includes a base part, a peripheral part, and a second connecting part that interconnects the peripheral part and the lower surface and that includes one of a curved surface, an inclined flat surface, and a combination thereof.

According to yet another aspect of the disclosure, the LED package includes a packaging substrate, an LED chip, and a light-transmissible unit. The packaging substrate has a first surface. The LED chip is disposed on the first surface. The light-transmissible unit is disposed on the first surface, and is formed with an indentation defined by an indentation-defining wall which cooperates with the first surface to form a cavity in which the LED chip is enclosed. The indentation-defining wall includes a base part and a peripheral part. The peripheral part has an upper portion adjacent to the base part, and a lower portion extending from the upper portion toward the packaging substrate. The upper portion forms an acute angle (a) with a normal line (Z) to the first surface.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic view illustrating a conventional light-emitting diode (LED) package.

FIG. 2 is a schematic view illustrating a first embodiment of an LED package according to the disclosure.

FIG. 3 is a schematic view illustrating a second embodiment of the LED package according to the disclosure.

FIG. 4 is a schematic view illustrating a third embodiment of the LED package according to the disclosure.

FIG. 5 is a schematic view illustrating a fourth embodiment of the LED package according to the disclosure.

FIG. 6 is a schematic view illustrating a fifth embodiment of the LED package according to the disclosure.

FIG. 7 is a schematic view illustrating a sixth embodiment of the LED package according to the disclosure.

FIG. 8 is a schematic view illustrating a seventh embodiment of the LED package according to the disclosure.

FIG. 9a is a simulation diagram illustrating stress distribution at a top portion of a light-transmissible unit of the conventional LED package shown in FIG. 1.

FIG. 9b is a simulation diagram illustrating stress distribution at a top portion of a light-transmissible unit of the LED package of the third embodiment.

FIG. 10a is a simulation diagram illustrating stress distribution at a bottom portion of the light-transmissible unit of the conventional LED package shown in FIG. 1.

FIG. 10b is a simulation diagram illustrating stress distribution at a bottom portion of the light-transmissible unit of the LED package of the third embodiment.

FIG. 11a is a simulation diagram illustrating stress distribution at a peripheral part of the light-transmissible unit of the conventional LED package shown in FIG. 1.

FIG. 11b is a simulation diagram illustrating stress distribution at a peripheral part of the light-transmissible unit of the LED package of the third embodiment.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

Referring to FIG. 2, a first embodiment of a light-emitting diode (LED) package according to the disclosure includes a packaging substrate 100, an LED chip 200, and a light-transmissible unit 300. The packaging substrate 100 has a first surface 1001 and a second surface 1002 that is opposite to the first surface 1001. The LED chip 200 is disposed on the first surface 1001 of the packaging substrate 100, and has an electrode structure (not shown). In addition, the light-transmissible unit 300 is disposed on the first surface 1001 of the packaging substrate 100.

The packaging substrate 100 may be any appropriate substrate, such as a ceramic substrate or a printed circuit board. A flat ceramic substrate is used for illustration in this embodiment. As shown in FIG. 2, the packaging substrate 100 has a functional area 110 on the first surface 1001. The LED package further includes an electrode pad 120 that is disposed on the second surface 1002 of the packaging substrate 100 and is connected to the functional area 110. The LED chip 200 is disposed on the functional area 110 and is connected to the functional area 110 via a gold wire or soldering. In certain embodiments, the functional area 110 is a metal plating layer that is formed on the first surface 1001, and that has a positive electrode portion and a negative electrode portion which are connected to the electrode structure of the LED chip 200. The electrode pad 120 is electrically connected to the electrode structure of the LED chip 200, and can be used for external electrical connection.

The LED chip 200 may be any type of chip, such as an ultraviolet (UV) LED chip which may emit light having a wavelength of less than 400 nm (e.g., from 200 nm to 385 nm), a deep ultraviolet (DUV) LED chip, and an LED chip which may emit light having a wavelength within a range of 600 nm to 760 nm. The LED chip 200 may have a thickness ranging from 200 μm to 750 μm. In certain embodiments, the thickness of the LED chip 200 ranges from 250 μm to 500 μm (e.g., 430 μm). It is comprehensible that the LED chip 200 may include a supporting substrate (not shown) and a semiconductor unit (not shown) formed on a surface of the supporting substrate. The semiconductor unit may include a first semiconductor layer, an active layer, and a second semiconductor layer sequentially formed on the surface of the supporting substrate. The electrode structure of the LED chip 200 is electrically connected to the first semiconductor layer and the second semiconductor layer. In addition, the LED chip 200 is connected to the functional area 110 of the packaging substrate 100 through the electrode structure. The electrode structure is connected to the functional area 110 by means of, for example, welding, eutectic bonding, etc., so as to fix the LED chip 200 to the packaging substrate 100. Moreover, the electrode structure of the LED chip 200 may be externally and electrically connected to an external device through the electrode pad 120 disposed on the second surface 1002 of the packaging substrate 100.

The light-transmissible unit 300 is attached to the first surface 1001 of the packaging substrate 100 by an adhesive layer (not shown), and may change the path of light emitted from the LED chip 200 by virtue of its refractive index, thereby adjusting a light-emitting angle of the light. The light-transmissible unit 300 may also collect light emitted from the LED chip 200, and hence can improve the luminous efficiency of the LED chip 200.

The light-transmissible unit 300 may include a base portion 320 and a light-transmissible portion 330. Referring to FIG. 2, in this embodiment, the light-transmissible unit 300 has a lens structure made of quartz glass, and the light-transmissible portion 330 is formed into a convex lens. In addition, the base portion 320 is located below the convex lens. Therefore, with the convex lens, the light-emitting angle of the light-transmissible unit 300 may range from approximately 30° to 70°. Moreover, the base portion 320 is attached to the first surface 1001 of the packaging substrate 100 such that the light-transmissible portion 330 is located above and registered with the LED chip 200. The light-transmissible unit 300 is formed with an indentation defined by an indentation-defining wall which cooperates with the first surface 1001 to form an cavity 310 in which the LED chip 200 is enclosed. The indentation-defining wall includes a base part 311 and a peripheral part 312. Each of the base part 311 and the peripheral part 312 includes one of a curved surface, a flat surface, and a combination thereof. The cavity 310 has a depth between the base part 311 and the first surface 1001, which ranges from about 100 μm to 900 μm, e.g., from 300 μm to 650 μm. In certain embodiments, a distance between the LED chip 200 and the base part 311 is greater than or equal to 20 μm to prevent undesired contact of the LED chip 200 with the indentation-defining wall resulting from process errors and the like. However, it should be noted that the distance between the LED chip 200 and the base part 311 cannot be too large, such as greater than 300 μm, so as to prevent the cavity 310 from having a depth that is too large, which results in an undesired increase in volumes of the light-transmissible unit 300 and the LED package.

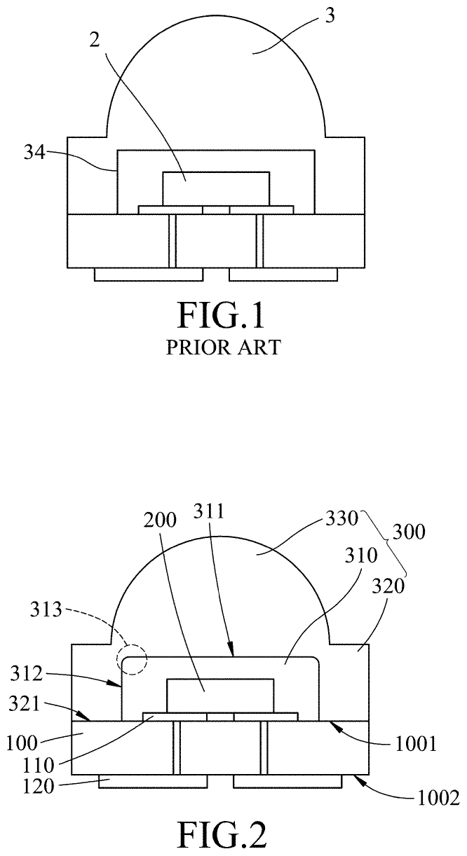

The indentation-defining wall may further include a first connecting part 313 that interconnects the base part 311 and the peripheral part 312 and that includes one of a curved surface, an inclined flat surface, and a combination thereof. In this embodiment, the first connecting part 313 is a curved surface with changes in slope. In certain embodiments, the first connecting part 313 includes a first curved surface and is formed as an arc shape. In other words, the indentation-defining wall has a rounded corner. In addition, the arc shape of the first connecting part 313 protrudes in a direction away from the cavity 310. The arc shape that is formed at the junction of the base part 311 and the peripheral part 312 replaces a right-angle shape as used in the prior art (see FIG. 1) so that the edge stress of the light-transmissible unit 300 at the first connecting part 313 can be reduced without affecting the light extraction efficiency of the LED chip 200. Therefore, the risk of edge cracking of the light-transmissible unit 300 during a manufacturing process can be reduced.

In an exemplary embodiment, the first curved surface of the first connecting part 313 has a radius of curvature ranging from 0.05 mm to 0.3 mm. If the radius of curvature of the first curved surface is less than 0.05 mm, the edge stress of the light-transmissible unit 300 cannot be effectively reduced. In addition, if the radius of curvature of the first curved surface exceeds 0.3 mm, it is unfavorable to the stability of the bonding between the light-transmissible unit 300 and the packaging substrate 100.

In an exemplary embodiment, the radius of curvature of the first curved surface of the first connecting part 313 ranges from 0.1 mm to 0.2 mm. The arc shape of the first connecting part 313 may greatly reduce the edge stress of the light-transmissible unit 300 at the first connecting part 313, thereby reducing the probability of cracking of the light-transmissible unit 300. Therefore, the packaging costs of the LED package can be reduced.

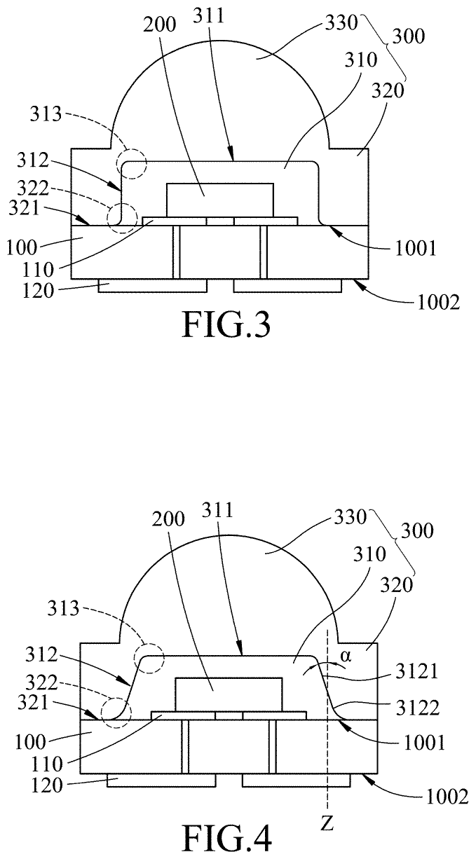

Referring to FIG. 3, a second embodiment of the LED package according to the disclosure has a structure similar to that of the first embodiment, and differences therebetween are described below.

In the second embodiment, the light-transmissible unit 300 further has a lower surface 321 that contacts with the first surface 1001, and the indentation-defining wall further includes a second connecting part 322 that interconnects the peripheral part 312 and the lower surface 321 and that has a curved surface with changes in slope. In certain embodiments, the second connecting part 322 includes a second curved surface and is formed as an arc shape. In addition, the arc shape of the second connecting part 322 protrudes in a direction toward the cavity 310. The arc shape that is formed at the junction of the lower surface 321 and the peripheral part 312 replaces a right-angle shape as used in the prior art (see FIG. 1), buffering the stress occurred at corners of the light-transmissible unit 300 so as to reduce the risk of edge cracking of the light-transmissible unit 300. As a result, the yield of the LED package can be improved without affecting the size and light extraction efficiency thereof. Therefore, the packaging costs of the LEG package can be reduced.

In this embodiment, the second curved surface of the second connecting part 322 has a radius of curvature ranging from 0.05 mm to 0.3 mm. If the radius of curvature of the second curved surface is less than 0.05 mm, the edge stress of the light-transmissible unit 300 cannot be effectively reduced. In addition, if the radius of curvature of the second curved surface exceeds 0.3 mm, it is unfavorable to the stability of the bonding between the light-transmissible unit 300 and the packaging substrate 100. In certain embodiments, the radius of curvature of the second curved surface ranges from 0.1 mm to 0.2 mm.

Referring to FIG. 4, a third embodiment of the LED package according to the disclosure has a structure similar to that of the second embodiment, and differences therebetween are described below.

In the third embodiment, the peripheral part 312 of the indentation-defining wall is outwardly inclined from the base part 311 to the lower surface 321 of the light-transmissible unit 300, and has an upper portion 3121 and a lower portion 3122. In other words, the cavity 310 has a width increasing along a direction from the base part 311 toward the first surface 1001. The upper portion 3121 is adjacent to the base part 311 and is connected to the first connecting part 313, and the lower portion 3122 extends from the upper portion 3121 toward the packaging substrate 100 and is connected to the second connecting part 322. The upper portion 3121 forms an acute angle (a) with a normal line (Z) to the first surface 1001. In an exemplary embodiment, the acute angle (a) is not less than 5°. In another exemplary embodiment, the acute angle (a) ranges from 5° to 60°. In this embodiment, the peripheral part 312 is an inclined flat surface, which makes the stress on the peripheral part 312 of the indentation-defining wall evenly distributed so that the stress can be transited smoothly. In addition, since the angle formed by the upper portion 3121 of the peripheral part 312 and the normal line to the first surface 1001 of the packaging substrate 100 is an acute angle, the cavity 310 is in the shape of an isosceles trapezoid. Therefore, the light extraction of the LED chip 200 can be enhanced, thereby improving the light extraction efficiency of the LED package.

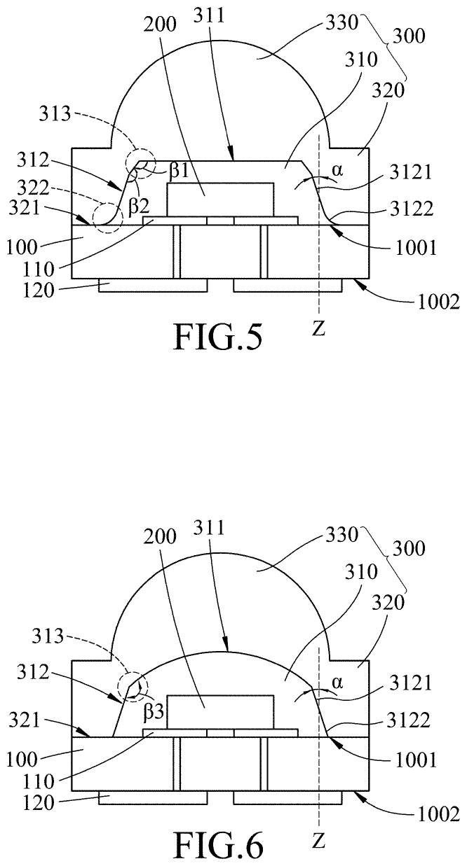

Referring to FIG. 5, a fourth embodiment of the LED package according to the disclosure has a structure similar to that of the third embodiment, and differences therebetween are described below.

In the fourth embodiment, the first connecting part 313 of the indentation-defining wall includes an inclined flat surface that forms a first obtuse angle (β1) with the base part 311 and that forms a second obtuse angle (β2) with the peripheral part 312. The inclined flat surface that is formed at the junction of the base part 311 and the peripheral part 312 replaces a right-angle shape as used in the prior art (see FIG. 1) so that the edge stress of the light-transmissible unit 300 can be reduced without affecting the light extraction efficiency of the LED chip 200. Therefore, the risk of edge cracking of the light-transmissible unit 300 can be reduced.

In certain embodiments, the second connecting part 322 may be an inclined flat surface that forms a third obtuse angle with the peripheral part 312 and that forms a fourth obtuse angle with the lower surface 321 of the light-transmissible unit 300. The inclined flat surface that is formed at the junction of the peripheral part 312 and the lower surface 321 replaces a right-angle shape as used in the prior art (see FIG. 1), which plays an important role in stress transition along the indentation-defining wall so as to reduce the risk of edge cracking of the light-transmissible unit 300. Therefore, the packaging costs of the LED package can be reduced without affecting the size and light extraction efficiency thereof.

Referring to FIG. 6, a fifth embodiment of the LED package according to the disclosure has a structure similar to that of the first embodiment, and the differences therebetween are described below.

In the fifth embodiment, the base part 311 of the indentation-defining wall is a curved surface, and the first connecting part 313 is formed by a curved surface and an inclined flat surface. In addition, the curved surface and the inclined flat surface of the first connecting part 313 form an obtuse angle (β3). In addition, the peripheral part 312 is inclined outwardly from the base part 311 toward the packaging substrate 100. The first connecting part 313 having the curved surface and the inclined flat surface replace the right-angle shape as used in the prior art (see FIG. 1) so that the edge stress of the indentation-defining wall can be effectively reduced.

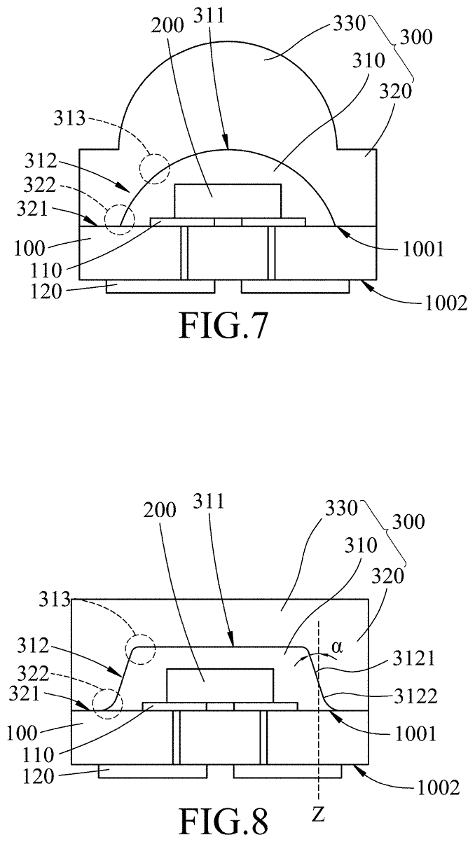

Referring to FIG. 7, a sixth embodiment of the LED package according the disclosure has a structure similar to that of the fifth embodiment, and differences therebetween are described below.

In the sixth embodiment, the first connecting part 313, the base part 311, and the peripheral part 312 are curved surfaces so that the indentation-defining wall is a curved surface and is formed as an arc shape. The arc-shaped indentation-defining wall can significantly reduce the edge stress. Therefore, the risk of edge cracking of the light-transmissible unit 300 can be reduced.

Referring to FIG. 8, a seventh embodiment of the LED package according to the disclosure has a structure similar to that of the third embodiment, and differences therebetween are described below.

In the seventh embodiment, the light-transmissible portion 330 of the light-transmissible unit 300 has a flat upper surface, rather than a convex surface as shown in the third embodiment. In other words, the light-transmissible portion 330 of the seventh embodiment is a cuboid, and not a convex lens. A light-emitting angle of the LED package in this embodiment may range from about 120° to 140°.

The conventional LED package shown in FIG. 1 and the LED package of the third embodiment are subjected to stress distribution simulation.

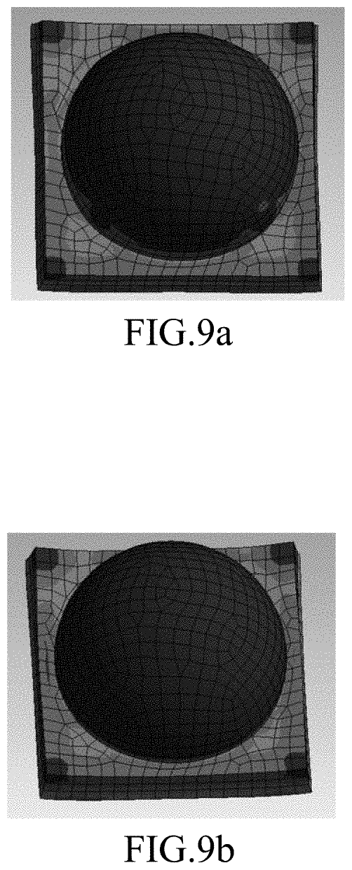

Referring to FIGS. 9a and 9b, the stress distribution at the top of the light-transmissible unit 3 of the conventional LED package is the same as that of the LED package of the third embodiment, indicating that the shape change of the indentation-defining wall in the third embodiment cannot induce location transfer of the stress on the light-transmissible unit 300, and therefore, the cracking sites on the light-transmissible unit 300 may not change. However, the magnitude of the stress can be reduced so as to reduce the cracking risk.

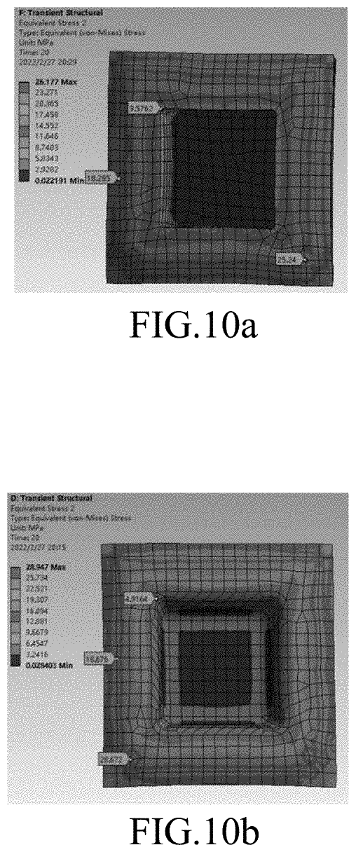

FIGS. 10a and 10b respectively illustrate the stress distributions at the bottom of the light-transmissible unit 3 of the conventional LED package and at the bottom of the light-transmissible unit 300 of the LED package of the third embodiment. As shown in FIG. 10a, the stress is mainly focuses at the base portion 320, and the maximum stress reaches 25.24 MPa. In addition, the edge stress at corners of the indentation-defining wall is 9.576 MPa. Under such stress distribution, cracking may occur at the corners of the indentation-defining wall. Referring to FIG. 10b, the stress distribution in the third embodiment is similar to that in the prior art. However, the edge stress at the corners of the indentation-defining wall of the third embodiment is significantly reduced to about 4.916 MPa, indicating that the arc shape that is formed at the junction of the lower surface 321 of the light-transmissible unit 300 and the peripheral part 312 can reduce the edge stress, thereby reducing the risk of cracking of the light-transmissible unit 300 during a packaging process.

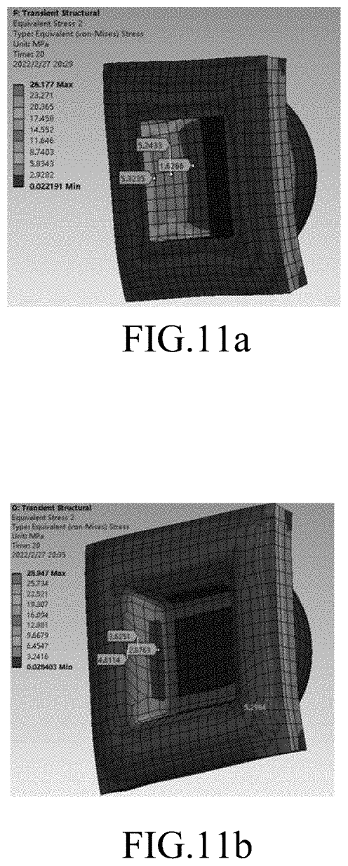

FIGS. 11a and 11b respectively illustrate the stress distributions at a peripheral part 34 (see FIG. 1) of the light-transmissible unit 3 of the conventional LED package and at the peripheral part 312 of the LED package of the third embodiment. As shown in FIG. 11a, the stress at the peripheral part 34 of the indentation-defining wall of the conventional LED package have a large distribution span, i.e., from 1.6266 MPa to 5.2433 MPa, which may cause uneven stress distribution and increase the burden on the peripheral part 34. However, referring to FIG. 11b, when the peripheral part 312 of the indentation-defining wall is the inclined flat surface as in the third embodiment, the stress on the peripheral part 312 have a smaller and continuous distribution span, i.e., from 2.8763 MPa to 3.6251 MPa so as to continuously transit stress, thereby reducing the burden of the peripheral part 312. Therefore, the risk of cracking along the indentation-defining wall can be reduced.

In summary, by forming the curved surface or the inclined flat surface at the first connecting part 313 and/or the second connecting part 322, which replaces the right-angle shape as used in the prior art, the edge stress of the light-transmissible unit 300 can be reduced without affecting the light extraction efficiency of the LED chip 200, thereby lowering the risk of edge cracking of the light-transmissible unit 300. Therefore, the packaging costs of the LED package can be reduced. In practical application, by forming the curved surface or the inclined flat surface at the first connecting part 313 and/or the second connecting part 322, the light-transmissible unit 300 is able to withstand a higher pressing force and a higher temperature compared with those in the prior art, which can enhance the fault tolerance in a manufacturing process under a harsh operating environment. Besides, with the peripheral part 312 of the indentation-defining wall being an inclined flat surface, the stress on the peripheral part 312 can be evenly distributed and hence can be transited smoothly. In addition, the inclined flat surface can enhance the light extraction of the LED chip 200, thereby increasing the light extraction efficiency of the LED package, thereby achieving the objects of the disclosure.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A light-emitting diode (LED) package, comprising:
a packaging substrate having a first surface;
an LED chip disposed on said first surface; and
a light-transmissible unit disposed on said first surface, and formed with an indentation defined by an indentation-defining wall which cooperates with said first surface to form a cavity in which said LED chip is enclosed, said indentation-defining wall including a base part, a peripheral part, and a first connecting part that interconnects said base part and said peripheral part and that includes one of a curved surface, an inclined flat surface, and a combination thereof.

2. The LED package of claim 1, wherein said first connecting part includes a first curved surface and is formed as an arc shape.

3. The LED package of claim 2, wherein said first curved surface has a radius of curvature ranging from 0.05 mm to 0.3 mm.

4. The LED package of claim 3, wherein the radius of curvature ranges from 0.1 mm to 0.2 mm.

5. The LED package of claim 1, wherein each of said base part and said peripheral part independently includes one of a curved surface, a flat surface, and a combination thereof.

6. The LED package of claim 1, wherein said peripheral part has an upper portion adjacent to said base part and a lower portion extending from said upper portion toward said substrate, said upper portion forming an acute angle with a normal line to said first surface.

7. The LED package of claim 6, wherein said acute angle is not less than 5°.

8. The LED package of claim 7, wherein said acute angle ranges from 5° to 60°.

9. The LED package of claim 1, wherein said light-transmissible unit has a lower surface that contacts with said first surface, said indentation-defining wall further including a second connecting part that interconnects said peripheral part and said lower surface and that includes one of a curved surface, an inclined flat surface, and a combination thereof.

10. The LED package of claim 1, wherein said cavity has a width increasing along a direction from said base part toward said first surface.

11. The LED package of claim 10, wherein said first connecting part includes said inclined flat surface that forms a first obtuse angle with said base part.

12. The LED package of claim 11, wherein said inclined flat surface forms a second obtuse angle with said peripheral part.

13. A light-emitting diode (LED) package, comprising:
a packaging substrate having a first surface;
an LED chip disposed on said first surface; and
a light-transmissible unit disposed on said first surface, having a lower surface that contacts with said first surface and formed with an indentation defined by an indentation-defining wall which cooperates with said first surface to form a cavity in which said LED chip is enclosed, said indentation-defining wall including a base part, a peripheral part, and a second connecting part that interconnects said peripheral part and said lower surface and that includes one of a curved surface, an inclined flat surface, and a combination thereof.

14. The LED package of claim 13, wherein said second part includes a second curved surface and is formed as an arc shape.

15. The LED package of claim 13, wherein each of said base part and said peripheral part independently includes one of a curved surface, a flat surface, and a combination thereof.

16. The LED package of claim 13, wherein said peripheral part has an upper portion adjacent to said base part and a lower portion extending from said upper portion toward said substrate, said upper portion forming an acute angle with a normal line to said first surface.

17. The LED package of claim 16, wherein said acute angle is not less than 5°.

18. A light-emitting diode (LED) package, comprising:
a packaging substrate having a first surface;
an LED chip disposed on said first surface; and
a light-transmissible unit disposed on said first surface, and formed with an indentation defined by an indentation-defining wall which cooperates with said first surface to form a cavity in which said LED chip is enclosed, said indentation-defining wall including a base part and a peripheral part, said peripheral part having an upper portion adjacent to said base part and a lower portion extending from said upper portion toward said packaging substrate, said upper portion forming an acute angle with a normal line to said first surface.

19. The LED package of claim 18, wherein said acute angle is not less than 5°.

20. The LED package of claim 19, wherein said acute angle ranges from 5° to 60°.
